(19) United States
(12) Patent Application Publication
(10) Pub. No.: US 2024/0183980 A1
(43) Pub. Date: Jun. 6, 2024

(54) OPTICAL PROXIMITY SENSOR

(71) Applicant: ams International AG, Jona (CH)

(72) Inventors: Krishna Kanth AVALUR, Hyderabad (IN); Rajesh GUPTA, Chennai (IN)

(21) Appl. No.: 18/285,181

(22) PCT Filed: Mar. 29, 2022
(86) PCT No.: PCT/EP2022/058298

§ 371 Date: Sep. 29, 2023

(30) Foreign Application Priority Data
Mar. 31, 2021 (DE) 10 2021 108 275.7

(51) Int. Cl. G01S 17/04; G01S 7/481; G09G 3/3208

(52) U.S. Cl. CPC G01S 17/04; G01S 7/4816; G09G 3/3208; G09G 2320/0626; G09G 2360/14

(57) ABSTRACT

An optical proximity sensor comprises a photodiode, a light source configured to emit light and a measurement circuit coupled to the photodiode. The measurement circuit is configured to measure light received by the photodiode in a first phase when the light source is turned off and in a second phase when the light source is turned on. The measurement circuit determines the difference between the light measured in the first and second phases, wherein the first phase for off measurement is longer than the second phase for on measurement.

### TECHNICAL FIELD

The present disclosure relates to an optical proximity sensor. Specifically, the present disclosure relates to an optical proximity sensor including photodiode, light source and measurement circuit to determine the difference between light sensed when the light source is turned off and light sensed when the light source is turned on. The present disclosure also relates to a mobile communication device including the optical proximity sensor.

### BACKGROUND

Optical proximity sensors are used in electronic devices to determine the proximity of an object relative to the electronic device. The object may be a portion of the body of an operator using the electronic device and the electronic device may be a mobile communication device such as a smartphone. In industry applications, the optical proximity sensor may be used to determine a proximity event of an object passing through a region. Proximity sensors may be based on light intensity measurements wherein a light source illuminates a target space so that the reflected light is a function of the distance of the nearest object to the sensor. At least two measurements may be performed to determine light received when a light source, such as a LED or a VCSEL, is turned on and with the light source turned off. The difference represents the reflected light which is a function of the proximity of the object. The subtraction of the on and off measurements removes the systematic ambient light. In conventional optical proximity sensors the first measurement having the light source on and the second measurement having the light source off are of equal duration.

In current smartphones, the optical proximity sensor and the light source may be placed behind the smartphone display which may be based on OLED (organic light-emitting diode) technology. In this case, there is a limit on how long the light source may be switched on without affecting the display distortion. There could also be some synchronization involved in the light source for proximity and the OLED display refresh signal.

The electronic devices used in the proximity sensor generate noise which effects the accuracy of the calculation. A major source of the noise in the measurement signals may be shot noise of the photodiode that receives the light during the on and off measurement phases. Shot noise becomes critical under high ambient light conditions which may involve situations with ambient light in the range of 100 klux or more.

There is a need in optical proximity sensors to improve the SNR (signal to noise ratio) of an optical proximity sensor. The SNR of the optical proximity sensor should be improved for high ambient light conditions to reduce the impact of the shot noise generated by the photodiode. The optical proximity sensor should be applicable to smartphone applications under behind OLED conditions where the sensor is placed behind the display screen.

It is an object of the present disclosure to provide an optical proximity sensor that has improved SNR.

It is another object of the present disclosure to provide an optical proximity sensor with improved SNR under high ambient light conditions.

It is yet another object of the present disclosure to provide an optical proximity sensor having improved SNR under high ambient light conditions in a behind-OLED situation.

It is yet another object of the present disclosure to provide a mobile communication device having an optical proximity sensor having improved accuracy.

### SUMMARY

One or more of the above-mentioned objects are achieved by an optical proximity sensor having the features of present claim 1.

An optical proximity sensor according to an embodiment comprises a photodiode to receive optical light. The sensor includes a light source which is configured to emit light during an on-phase of the light source. The light source may be a LED (light-emitting diode) or a VCSEL (vertical cavity surface emitting laser) or another light source that may be formed by integrated circuit technology. The optical proximity sensor includes a measurement circuit that is coupled to the photodiode so that the measurement circuit evaluates light received through the photodiode. The measurement circuit is operable and configured to measure light received by the photodiode in a first phase when the light source is turned off so that ambient light only is received by the photodiode and evaluated by the measurement circuit. The measurement circuit is further operable and configured to measure light received by the photodiode in a second phase when the light source is turned on so that ambient light plus light emitted by the light source and reflected by an object is received by the photodiode and evaluated. The measurement circuit determines the difference between the light measured in the first phase and the second phase. The light measurements are subtracted from each other so that the reflected light is separated and serves as a measure to indicate the proximity event of the object. It is possible to also have light source on in the first phase and off in the second phase and light measurements subtracted in an electronic circuit appropriately to estimate the reflected light. The second phase may be performed after the first phase or the first phase may be performed after the second phase.

According to the embodiment, the first phase when the light source is turned off is longer than the second phase when the light source is turned on so that the measurement during the first phase is longer than the measurement during the second phase. More light is received and evaluated during the off phase so that more signal energy is received compared to the noise generated in the circuit, especially the shot noise of the photodiode. The measurement time during the second phase when the light source is on is limited by the acceptable distortion generated by the light source in a behind-OLED situation. Practically, the first phase may be an integer multiple of the second phase which may be two times or four times or eight times or even higher integer times of the second phase.

Applying the first phase longer than the second phase may be realized by a first and by an alternative second embodiment. According to the first embodiment, the first phase, when the light source is off to measure the ambient light, comprises a consecutive performance of a first sub-phase and a second sub-phase, wherein light is measured during each of the first and second sub-phases.

The measurement circuit comprises an integrator which is coupled to the photodiode, a sum and hold circuit which is coupled downstream of the integrator and a capacitor arrangement to sample the integrator output voltage signal which is disposed between the integrator and the sum and hold circuit.

The capacitor arrangement comprises at least a first and a second capacitor wherein selectively one of said capacitors is operatively connected between the output of the integrator and the input of the sum and hold circuit during the at least first and second sub-phases of the first phase, which is the off phase. A parallel connection of the first and second capacitors is operatively connected between the output of the integrator and the input of the sum and hold circuit during the second phase, which is the on phase of the light source. Accordingly, during the first phase only one of the capacitors is operative, during the second phase, both capacitors are operative in a parallel connection as the average charge is transferred to the sum and hold circuit.

As the first phase is longer than the second phase and comprises a first sub-phase and a second sub-phase, the first capacitor is operative during the first sub-phase and the second capacitor is operative during the second sub-phase.

Such sub-phases can be extended to higher than two where more capacitors are connected as a parallel array at the sum and hold input where each capacitor stores the integration voltage for one sub-phase.

The operation of the first and second capacitors during first sub-phase, the second sub-phase and the second phase is achieved by switches disposed between one of the capacitor plates and the output of the integrator and another one of the capacitor plates and the input of the sum and hold circuit. The switches are operated such that the first and second switches connected to the first capacitor are conductive during the first sub-phase and non-conductive during the second sub-phase to achieve that the first capacitor is operative during the first sub-phase and decoupled during the second sub-phase. The third and fourth switches connected to the second capacitor are non-conductive during the first sub-phase and conductive during the second sub-phase so that the second capacitor is operative during the second sub-phase and decoupled during the first sub-phase.

The capacitors in the capacitor arrangement are controlled by corresponding control signals which perform a switching of the first and second switches out of phase compared to the third and fourth switches during the first and second sub-phases of the first phase. The first and second switches are conductive when the third and fourth switches are non-conductive and vice versa.

The capacitor arrangement may comprise at least four capacitors disposed between integrator output and input of the sum and hold circuit. During the first phase, which is the off phase of the light source, a single one of said four capacitors is associated to one of the sub-phases. Having four sub-phases, a different one of the four capacitors is associated to each one of the sub-phases so that it is operatively connected between integrator output and sum and hold circuit input, wherein the other capacitors are disconnected. The four capacitors may have equal capacitance. Each sub-phase of the first phase is associated to one of the capacitors. The principle can be extended to more than four capacitors, such as eight capacitors and so forth.

During operation of the capacitor arrangement an output signal is received from the integrator and a charge is stored in the individual capacitors of the capacitor arrangement. A noise averaging is performed during the first and second sub-phases of the first phase. The signal from the integrator includes a useful signal portion and a noise portion, wherein noise averaging reduces the noise portion.

The sum and hold circuit comprises an amplifier connected downstream of the capacitor arrangement which includes at least one capacitor connected between input and output of the amplifier and a switch connected parallel to the capacitor. The sum and hold circuit is configured and operative to generate an output signal that represents the difference between the charge stored in the capacitors of the capacitor arrangement at the end of the first phase, that is at the end of the last sub-phase of the first phase, and the charge stored in the capacitors of the capacitor arrangement at the end of the second phase.

The signal at the output of the sum and hold circuit which comprises the difference between the charges from the capacitor arrangement at the end of the first and second phases is forwarded to an ADC (analog-to-digital converter) to convert the analog voltage signal to a digital code which may be a bitstream or a digital word useful for further use to control operation of the circuit.

According to the second alternative embodiment, the integrator generates a first signal that represents the amount of light received by the photodiode during the first phase when the light source is off and a second signal that represents the amount of light received by the photodiode during the second phase when the light source is on. The measurement circuit normalizes the first signal when the light source is off by the ratio of durations or lengths of the first and the second, off and on, phases. The sum and hold circuit generates the difference between the normalized first signal of the off phase and the second signal of the on phase.

The integration capacitor of the integrator disposed between input and output of the integrator is increased by said ratio of the lengths of the first and second phases so that the gain of the integrator is changed from the first to the second phase.

Concerning applications of the proximity sensor in a larger device, the output signal from the optical proximity sensor may be used in a mobile communication device such as a smartphone, wherein the proximity sensor including the light source is disposed behind the display. The output signal from the optical proximity sensor serves as an indicator of the level of proximity of an object relative to the mobile communication device and may be used to control the brightness of the display. For example, when an object is proximate, which may be the case when a user of a smartphone receives a telephone call, the brightness of the display is reduced or shut off. When no object is determined to be proximate, the brightness of the display is operated as normal.

It is to be understood that both the foregoing general description and the following detailed description are merely exemplary, and are intended to provide an overview or framework to understand the nature and character of the claims. The accompanying drawings are included to provide a further understanding and are incorporated in, and constitute a part of, this description. The drawings illustrate one or more embodiments, and together with the description serve to explain principles and operation of the various embodiments. The same elements in different figures of the drawings are denoted by the same reference signs.

### BRIEF DESCRIPTION OF THE DRAWINGS

In the drawings:

FIG. 1 shows a top view on a mobile communication device including an optical proximity sensor;

FIG. 2 shows a detailed schematic diagram of an optical proximity sensor according to a first embodiment;

FIG. 3 shows the operational steps performed in an optical proximity sensor according to the first embodiment;

FIG. 4 shows signals from the circuit of FIG. 2;

FIG. 5 shows clock signals controlling the switches in the circuit of FIG. 2; and

FIG. 6 shows operational steps in an optical proximity sensor according to the second embodiment.

### DETAILED DESCRIPTION OF EMBODIMENTS

The present disclosure will now be described more fully hereinafter with reference to the accompanying drawings showing embodiments of the disclosure. The disclosure may, however, be embodied in many different forms and should not be construed as limited to the embodiments set forth herein. Rather, these embodiments are provided so that the disclosure will fully convey the scope of the disclosure to those skilled in the art. The drawings are not necessarily drawn to scale but are configured to clearly illustrate the disclosure.

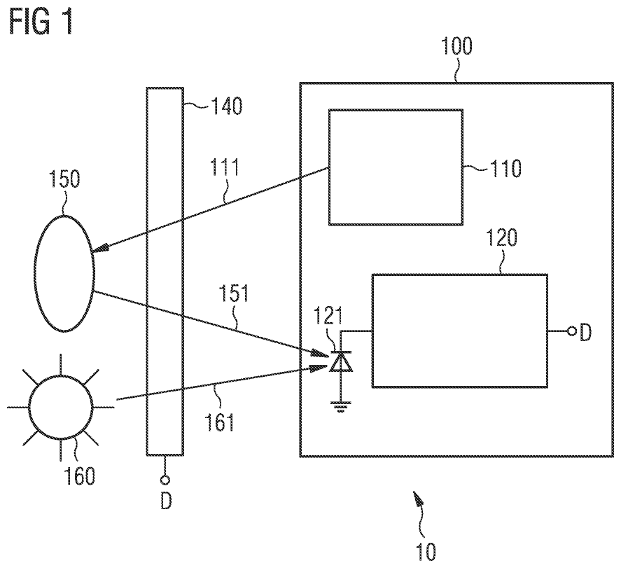

FIG. 1 shows a block diagram of a mobile communication device 10 such as a smartphone. The smartphone 10 comprises a display 140 which separates the environment from the internal devices. Display 140 may use OLED technology. During use of the smartphone 10, an object 150 that may be a portion of the body of the person using the smartphone, may be close to the front surface of the display 140 so that control of operation of the smartphone is to be made in response to the detection of the proximity of object 150 close to display screen 140. Smartphone 10 comprises an optical proximity sensor 100 disposed fully below the display 140. Optical proximity sensor 100 generates a signal D which indicates the event of or the level of proximity of the object 150 relative to display 140 and controls the brightness of screen 140 in dependence on the signal D. Other features of smartphone 10 may also be controlled by signal D. Sensor 100 comprises a light source 110 which may include a LED or a VCSEL that generates an outgoing light beam 111 passing the display 140 into the environment. Emitted light beam 111 is reflected by object 150 so that a reflected light beam 151 passes back through display 140. Furthermore, ambient natural light and/or artificial light from a light bulb 160 penetrates through display 140 as ambient light beam 161. Sensor 100 includes a measurement circuit 120 connected to a light-receiving element such as a photodiode 121 and determines a proximity event generating signal D. Photodiode 121 receives ambient light 161, reflected light 151 and (not shown) crosslight from light source 110 reflected at the inner surface of display 140. As the light source is placed behind the display it affects the display so that the on time of the light source is limited to avoid distortion of the display.

The light source 110 illuminates the space and the reflected light is a function of the distance of the nearest object to the sensor. In order to accurately measure this reflected light and subtract out the ambient, at least two measurements are necessary, one with the illuminating light source 110 turned on and one with light source 110 turned off. The difference is a measure of the reflected light and therefore a measure for the proximity of object 150 to device 10. The operation of the circuits is subject to noise which is particularly caused by the shot noise of the photodiode 121, which may be a problem under high ambient light conditions of, for example, more than 100 klux.

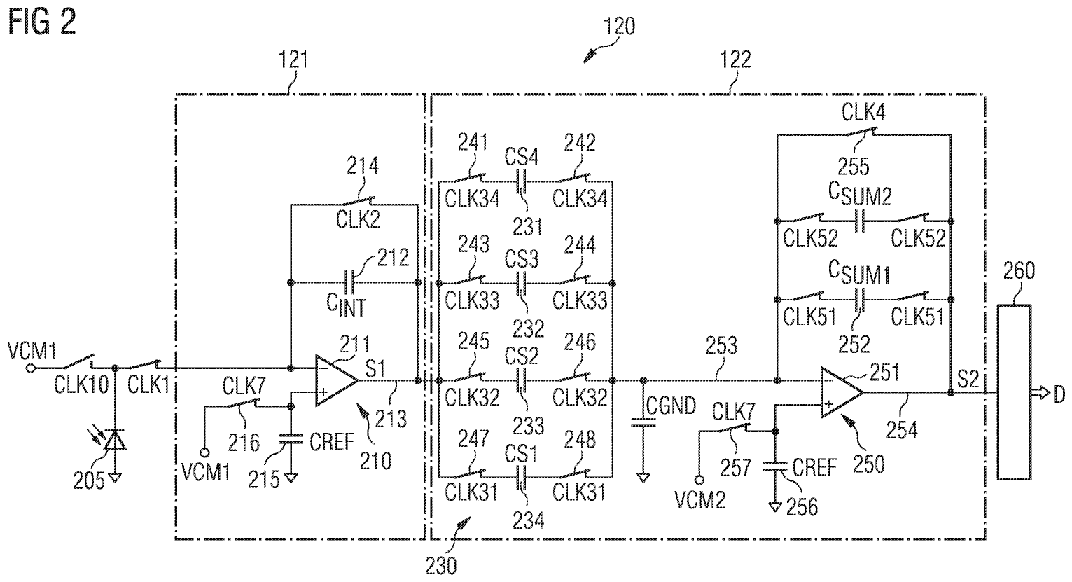

FIG. 2 shows a detailed schematic diagram of the measurement circuit 120. The measurement circuit 120 comprises a first stage 121 that is connected to the photodiode 205 and a second stage 122 connected downstream of the first stage 121. The first stage 121 performs an integration of the current generated by the photodiode 205, which is forwarded to the second stage 122 which includes a sum and hold circuit to generate the difference between the integration results during on and off time periods. The resulting voltage from the second stage 122 is analog-to-digital converted in a DA-converter 260 generating digital data code D.

Photodiode 205 is disposed behind the display of a smartphone and receives ambient light only in a first measurement phase and ambient light plus the reflected light in a second measurement phase. The reflected light results from light generated by the light source 110 which may be a VCSEL generating light at a defined wavelength such as 940 nm and reflected at an object.

First stage 121 includes an integrator 210 which comprises an operational amplifier 211 of which the inverting input is coupled to photodiode 205. A capacitor 212 is connected between inverting input and output 213 of amplifier 211. The non-inverting input of amplifier 211 is connected to a reference capacitor 215 and may be charged through a switch 216 with reference potential VCM1. A switch 214 is connected in parallel to feedback capacitor 212 to initialize the integrator. The output signal S1 of the integrator 210 includes portions such as a reset portion during which the integrator is set to an initial state, an integration portion during which the current from photodiode 205 is applied to the integrator and integrated in capacitor 212, and a hold portion during which integration is stopped and the integrated signal S1 is sampled and forwarded to the second stage 122.

The second stage 122 includes a sampling capacitor arrangement 230 comprising, in the present case, four capacitors 231, 232, 233, 234. Corresponding switches are provided to either plate of the capacitors to couple the capacitors to the output 213 of integrator 210 and the input 253 of the downstream connected sum and hold circuit 250. Capacitor 231 is connected through switch 241 to output 213 of integrator 210 and through switch 242 to input 253 of sum and hold circuit 250. Capacitor 232 is connected through switch 243 to output 213 and through switch 244 to input 253. Correspondingly, capacitor 233 has switches 245, 246 and capacitor 234 has switches 247, 248 for connection to terminals 213, 253. During operation, only one of the capacitors 231, 232, 233, 234 is selected and operative so that it is connected between output 213 of integrator 210 and input 253 of sum and hold circuit 250 during the off phase of light source 110 and the first measurement phase. The parallel connection of the four shown capacitors is connected between output 213 and input 253 during the on phase of light source 110 and the second measurement phase, as explained in more detail below.

The second stage 122 includes sum and hold circuit 250 connected downstream of capacitor arrangement 230. Sum and hold circuit 250 includes an operational amplifier 251 of which the inverting input 253 is connected to the capacitor arrangement 230. At least one capacitor 252 is connected between inverting input and output 254 of operational amplifier 251. A switch 255 is connected in parallel to capacitor 252. Another capacitor may be connected in parallel to capacitor 252. The non-inverting input of amplifier 251 is connected to a reference capacitor 256 and through a switch 257 to another reference potential VCM2. Sum and hold circuit 250 receives the voltages from the capacitor arrangement 230 during on and off measurement phases and forms the difference between the corresponding voltage signals supplied by the capacitor arrangement to subtract out the ambient light portion so that the reflected light portion remains as a measure for the proximity of object 150 relative to display 140.

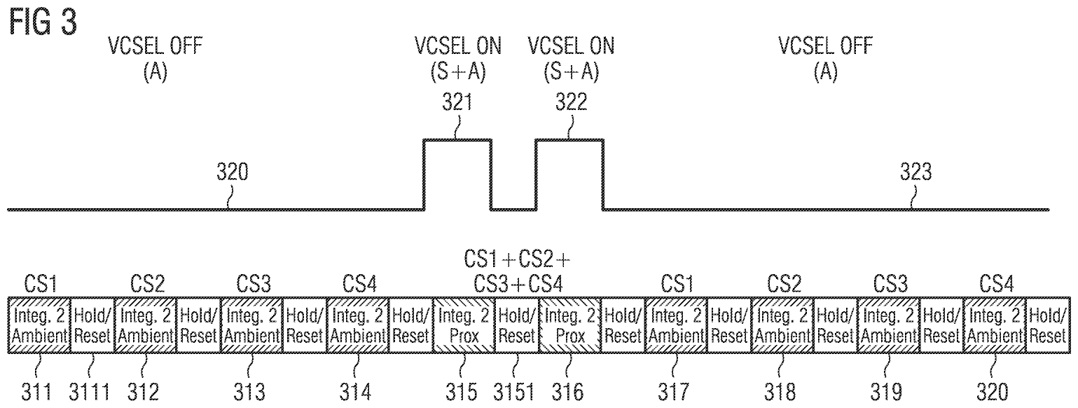

Operation of the circuit of FIG. 2 is now explained in connection with FIG. 3, which shows operational phases of the circuit of FIG. 2. The upper portion of FIG. 3 represents the operation of the light source 110. During a first phase 320 when the light source formed by a VCSEL is off, only ambient light A is received by photodiode 205. During a consecutive second phase 321 when the VCSEL is on, photodiode 205 receives ambient light A and a light signal S from the light source reflected by an object receiving a combination of ambient light plus reflected light S+A. The process is continued with another on phase 322 and another off phase 323. The sequence off-on-on-off is useful to reduce the effect of flicker from artificial light sources such as light bulbs, halogen lights or LEDs.

The off time measurement is considerably longer than the on time measurement. According to the first embodiment of which the operational phases are shown in the lower portion of FIG. 3, the off time measurement comprises four off measurement cycles 311, 312, 313, 314 measuring ambient light only performed one after the other. After the fourth ambient light measurement 314, an on measurement is performed synchronously with an on phase of the light source 110 represented by phase 315. The off measurement phases are four times longer than the on measurement phase, wherein the off measurement phase comprises four individual off measurement sub-phases 311, 312, 313, 314.

Then, a measurement cycle of on and off phases is performed wherein the sequence is reversed in that, first, an on measurement phase 316 is performed, followed by four consecutive off measurement phases 317, 318, 319, 320. One individual on or off measurement phase such as 311 or 315 includes integration of ambient light in 311 or integration of ambient plus reflected light in 315 followed by a hold phase 3111 an 3151, respectively, and a reset phase to prepare the circuit for the next measurement phases 312 and 316, respectively. During phase 311 only capacitor 234 having capacitance CS1 is operative and operatively connected between the output 213 of the first stage and the input 253 of the sum and hold circuit. During the phases 312, 313, 314 capacitor 234 of capacitance CS1 is shut off and another one of the capacitors, such as 233 having capacitance CS2 during phase 312, capacitor 232 having capacitance CS3 during phase 313 and capacitor 231 having capacitance CS4 during phase 314, is operative. The capacitors 231, . . . , 234 have equal capacitance so that CS1=CS2=CS3=CS4. During the on measurement phase, all four capacitances 231, . . . , 234 are connected parallel to each other so that the effective capacitance between output 213 of the first stage and input 253 of the sum and hold circuit is the sum of capacitances CS1+CS2+CS3+CS4. The individual and parallel connection of the capacitances 231, . . . , 234 are achieved by the switches 241, 242, . . . , 247, 248. The switches are operated by corresponding control signals CLK34, . . . , CLK31 that provide corresponding control signals to open or close the switches and cause the switches to be non-conductive and conductive, resp.

The impact of noise is improved so that the SNR (signal to noise ratio) is lower than in a conventional case that has only one single sampling capacitor disposed between first and second stages for on and off measurement phases. The following equations apply to the circuit in FIG. 2.

The shot noise current in the photodiode is given as:

Shot noise current=sqrt(qI/ton),

wherein q is the electron charge, I is the photocurrent and ton is the ontime which is mostly identical to the integration time.

The shot noise voltage is given as:

Shot noise voltage=sqrt(qIton/Cint²), wherein

Cint is the capacitance of integration capacitor 212.

Each integration of off phase produces certain noise voltage Vnoise1 for a given signal voltage Vsignal1.

The signal and noise charges, after averaging, onto second stage are:

Second stage input signal=Vsignal1*CS1/4+Vsignal2*CS2/4+Vsignal3*CS3/4+Vsignal4*CS4/4

Noise charge=sqrt(Vnoise1²*CS1²/16+Vnoise2²*CS2²/16+Vnoise3²*CS3²/16+Vnoise4²*CS4²/16)

### Considering:

Vsignal1=Vsignal2=Vsignal3=Vsignal4=Vsignal
Vnoise1=Vnoise2=Vnoise3=Vnoise4=Vnoise
CS1=CS2=CS3=CS4=CS/4
   leads to:
Signal charge=Vsignal*CS
Noise charge=Vnoise*CS/2
SNR=2 Vsignal/Vnoise

By comparison, in a conventional sensor having equal off and on measurement times and correspondingly equal capacitances in the off and on measurement phases:
Second stage input signal=Vsignal*CS
Noise charge=Vnoise*CS
SNR=Vsignal/Vnoise

The SNR of the circuit according to FIG. 2 reveals an improvement of a factor of 2 compared to a conventional case. The SNR improvement is a function of the number of off-phases used per on-phase. The higher the number of off-phases per on-phase, the higher is the improvement in the SNR at the first stage integrator output.

With the embodiment shown in FIG. 2, when the VCSEL is off and only ambient light is sensed, the ambient measurement integration is performed for a longer time. During proximity measurement when the VCSEL is on and reflected signal plus ambient light plus possible crosstalk is measured, the measurement time is shorter than during the off time measurement. However the on measurement is as long as possible, thereby avoiding distortion in the display as the light source is disposed behind the display. The extended off measurement reduces the effect of shot noise. The off measurements are performed multiply with one capacitor operative only, wherein the voltage noise from the photodiode is averaged out at the first stage output as well as the thermal noise generated by the first stage integrator. The circuit uses four individual capacitors during the off phase and the parallel combination of the four capacitors during the on measurement phase, wherein the off measurement phase is subdivided into four consecutive measurement sub-phases using only one capacitor. This principle can be reduced to two measurement sub-phases and two capacitors or extended to eight or even more capacitors corresponding to eight or more off measurement sub-phases. The reduction in noise in the total measurement is about 30% using four measurement sub-phases and four capacitors in the capacitor array. This technique does not increase power consumption as the VCSEL is off during the longer off measurement phase. It does not significantly increase the capacitor area as the required capacitance is split into equal parts for the analog averaging process.

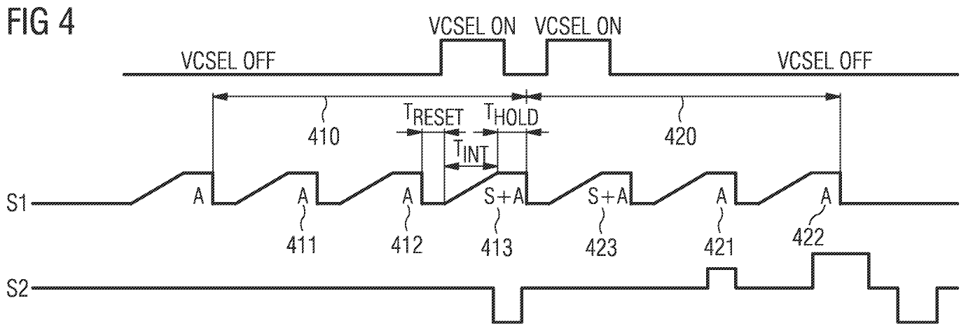

FIG. 4 shows signals from the circuit of FIG. 2. Signal S1 is provided at the output 213 of the integrator 210 and signal S2 is provided at the output 254 of the sum and hold circuit 250. One phase of signal S1 shows the consecutive sequence of a reset phase T_{RESET} where the integrator is brought into an initialization configuration. Then, an integration phase T_{INT} is performed in which the current form the photodiode is integrated into the capacitor 212 of the integrator so that the output of the integrator rises. Then, a hold phase T_{HOLD} is used to transfer the signal from the integrator to the capacitor arrangement. In the example shown in FIG. 4, each one of the measurement cycles 410 or 420 comprises two off measurement phases 411, 412 and 421, 422 and one on measurement phase 413 and 423. The sequence of on and off phases is reversed from measurement cycle 410 to measurement cycle 420 to reduce flicker effects from artificial lighting. Signal S2 at the output of sum and hold circuit takes the difference of the first stage outputs, which is the measurement of signal plus ambient minus ambient and stores the signal in the capacitors of the sum and hold circuit. Since the sequence of signal plus ambient (on) and ambient (off) phases are changed as off-off-on-on-off-off, the difference of the first two pulses of signal S2 gives the output in one direction (to the negative) and the difference of the last two pulses gives the final output in the opposite direction (to the positive), as shown in FIG. 4.

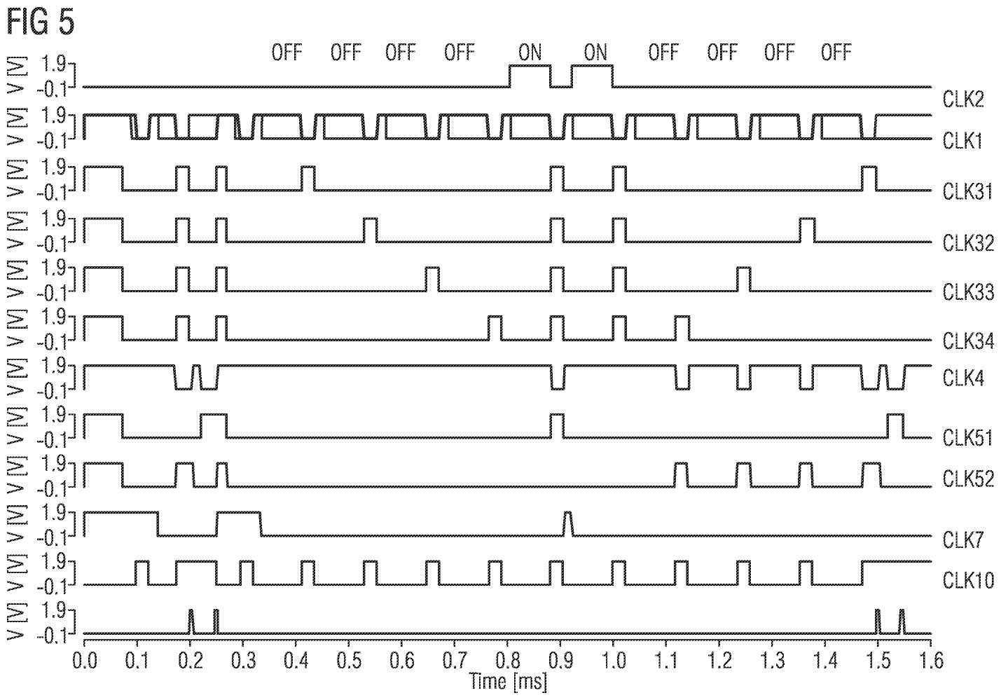

FIG. 5 shows an example of waveforms of signals from the circuit of FIG. 2. FIG. 5 shows the operation with four off sub-phases and one on phase that constitute a proximity measurement cycle, wherein the second cycle has reversed on and off sequences. Signals CLK1, CLK2 are applied to the switches connected to the photodiode and to the integration capacitor to switch between reset and integration phases. Signals CLK31, CLK32, CLK33, CLK34 operate the switches in the capacitor arrangement 230. As can be gathered from FIG. 5, during the off phases only one of said clock signals CLK31, . . . , CLK34 is active while the other clock signals are inactive. During an on measurement phase, all four clock signals CLK31, . . . , CLK34 are active so that all four capacitors are connected parallel to each other. Signal CLK4 operates the switch 255 connected in parallel to the capacitor 252 of the sum and hold circuit 250. Clock signals CLK51, CLK52 operate the switches connected to the capacitors in the sum and hold circuit. Signals CLK7, CLK10 are used to drive the reference capacitors and the photodiode to a corresponding common mode voltage VCM1, VCM2.

According to the second embodiment, the integrator generates a first signal that represents the amount of light received by the photodiode during the off phase. The integrator further generates a second signal that represents the amount of light received by the photodiode during the on phase so that the measurement time with the illuminating light may be fixed but the time of integration/measurement when the light source is off is increased. The ambient light during the off phase of the light source is integrated and measured for longer than ambient light plus signal light during the on phase of the light source. The off measurement light counts are normalized by the ratio of on/off time durations before the subtraction in a sum and hold circuit. This technique reduces the noise in the measurement of ambient light and improves the overall shot noise by a factor of up to SQRT (2). Accordingly, the measurement circuit is configured to normalize the first signal generated during the off phase by the ratio of lengths between first and second phases and then the sum and hold circuit generates the difference between the normalized first signal and the second signal obtained during the on phase.

The ambient light measurement during the off phase may be four to eight times longer than the measurement during the on phase. It may be necessary to use different gain of the integrator during the off and the on measurement phases which can be achieved by the adaption of the integration capacitance by the ratio of lengths of first and second phases. According to the second embodiment, the capacitance during the off phase is larger than during the on phase by the ratio of lengths of first and second phases.

The first and second embodiments increase the measurement time during the off phase and thereby reduce the shot noise improving the SNR. The first embodiment as depicted in FIG. 2, retains the same signal path during off and on measurement phases in the integrator and performs analog averaging of the multiple off-phase pulses. The circuit of the second embodiment normalizes the signal by the ratio of off and on phase durations and may adapt the gain of the integration signal path.

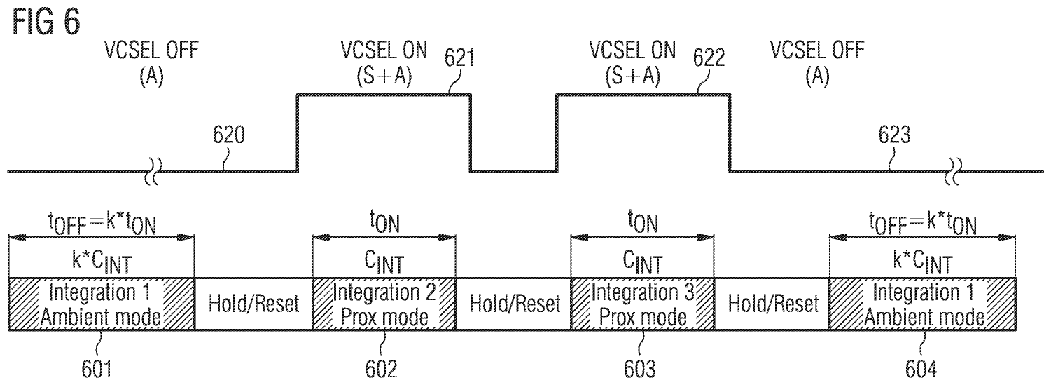

FIG. 6 shows operational phases of a proximity sensor according to the second embodiment. The off and on phases of the VCSEL light source are shown at 620, 621, 622, 623, wherein the sequence of off and on phases is reversed during the second measurement cycle to cope with flicker effects. During the VCSEL off phase 620, an integration is performed for an off time integration toff which is k times of the on time integration ton, wherein k is an integer number larger than 1. The integration capacitance may be increased by the factor k during the off time integration so that the integration capacitance is k*Cint with k being the factor between the off time integration and on time integration, k=toff/ton. During the on time integration 621, the integration capacitance is reduced to Cint.

It will be apparent to those skilled in the art that various modifications and variations can be made without departing from the spirit or scope of the disclosure as laid down in the appended claims. Since modifications, combinations, sub-combinations and variations of the disclosed embodiments incorporating the spirit and substance of the disclosure may occur to the persons skilled in the art, the disclosure should be construed to include everything within the scope of the appended claims.

This patent application claims the priority of German patent application with application No. 102021108275.7, the disclosure content of which is hereby incorporated by reference.

### REFERENCE SIGNS

10 mobile communication device
110 light source
120 measurement circuit
140 display
210 integrator
121 first stage
122 second stage
205 photodiode
230 capacitor array
250 sum and hold circuit
260 analog to digital convertor
231, . . . , 234 capacitors
241, . . . , 248 switches
212, 252 capacitors
211, 251 operational amplifiers
311, . . . , 320 measurement phases and sub-phases
CLK1, . . . CLK52 clock signals
S1, S2 signals
CS1, . . . , CS4 capacitances

1. An optical proximity sensor, comprising:
a photodiode;
a light source configured to emit light;
a measurement circuit coupled to the photodiode, the measurement circuit configured to measure light received by the photodiode in a first phase when the light source is turned off and in a second phase when the light source is turned on by an integration of an output signal of the photodiode and configured to determine the difference between the light measured in the first and second phases, wherein a time of integration in the first phase is longer than a time of integration in the second phase.

2. The optical proximity sensor of claim 1, wherein the first phase comprises at least a first sub-phase and a second sub-phase performed consecutively.

3. The optical proximity sensor of claim 2, wherein the measurement circuit comprises an integrator coupled to the photodiode, a sum and hold circuit coupled downstream the integrator and a capacitor arrangement disposed between the integrator and the sum and hold circuit,
wherein the capacitor arrangement comprises at least a first and a second capacitor,
wherein selectively one of the first and second capacitors is operatively connected between an output of the integrator and an input of the sum and hold circuit during the first phase and a parallel connection of the first and second capacitors is operatively connected between the output of the integrator and the input of the sum and hold circuit during the second phase.

4. The optical proximity sensor of claim 3, wherein the first capacitor is operatively connected between the output of the integrator and the input of the sum and hold circuit during the first sub-phase and the second capacitor is operatively connected between the output of the integrator and the input of the sum and hold circuit during the second sub-phase.

5. The optical proximity sensor of claim 3, wherein the capacitor arrangement further comprises:
a first switch connected between the output of the integrator and the first capacitor;
a second switch connected between the input of the sum and hold circuit and the first capacitor;
a third switch connected between the output of the integrator and the second capacitor; and
a fourth switch connected between the input of the sum and hold circuit and the second capacitor.

6. The optical proximity sensor of claim 5, wherein the capacitor arrangement is configured to set:
the first and second switches conductive during the first sub-phase and non-conductive during the second sub-phase;
the third and fourth switches non-conductive during the first sub-phase and conductive during the second sub-phase.

7. The optical proximity sensor of claim 5, wherein the capacitor arrangement is configured to operate the first and second switches out of phase to the third and fourth switches during the first phase.

8. The optical proximity sensor of claim 3, wherein the capacitor arrangement comprises at least four capacitors disposed between the output of the integrator and the input of the sum and hold circuit, wherein the first phase comprises at least four sub-phases performed consecutively and a single one of the at least four capacitors is associated to one of the at least four sub-phases and a parallel connection of the at least four capacitors is associated to the second phase.

9. The optical proximity sensor of claim 8, wherein the each one of the at least four capacitors has the same capacitance.

10. The optical proximity sensor of claim 3, wherein the sum and hold circuit comprises an amplifier connected downstream the capacitor arrangement, at least one capacitor connected between an input and an output of the amplifier and a switch connected parallel to the capacitor, the sum and hold circuit configured to generate an output signal representing the difference between the charge stored in the capacitors of the capacitor arrangement at the end of the first phase and the charge stored in the capacitors of the capacitor arrangement at the end of the second phase.

11. The optical proximity sensor of claim 3, wherein the integrator is configured to generate an output signal at the output of the integrator comprising a useful signal portion and a noise portion, wherein the capacitor arrangement is configured to average the noise portions provided by the integrator during the first and second sub-phases.

12. The optical proximity sensor of claim 3, further comprising an analog-to-digital converter disposed downstream the sum and hold circuit to generate a digital code representative of the difference of light received during the first and the second phases.

13. The optical proximity sensor of claim 1, the measurement circuit comprising:
an integrator configured to generate a first signal representing the amount of light received by the photodiode during the first phase and to generate a second signal representing the amount of light received by the photodiode during the second phase, the measurement circuit configured to normalize the first signal by the ratio of the lengths of the first phase and the second phase; and
a sum and hold circuit configured to generate the difference between the normalized first signal and the second signal.

14. The optical proximity sensor of claim 13, wherein the integrator comprises an integration capacitor connected between an input and an output of the integrator, wherein the capacitance of the integration capacitor is increased by the by the ratio of the lengths of the first phase and the second phase.

15. A mobile communication device, comprising:
a display; and
the optical proximity sensor according to claim 1, wherein the light source is disposed behind the display.

16. The mobile communication device of claim 15, wherein the brightness of the display is controlled in dependence on the level of proximity determined by the optical proximity sensor.
